(19) United States
(12) Patent Application Publication
(10) Pub. No.: US 2024/0376615 A1
(43) Pub. Date: Nov. 14, 2024

(54) ELECTROLYSER SYSTEM AND METHOD OF ELECTRODE MANUFACTURE

(71) Applicant: SUNGREENH2 PTE. LTD., Singapore (SG)

(72) Inventor: Saeid Masudy Panah, Singapore (SG)

(73) Assignee: SUNGREENH2 PTE. LTD., Singapore (SG)

(21) Appl. No.: 18/781,675

(22) Filed: Jul. 23, 2024

Related U.S. Application Data
(63) Continuation-in-part of application No. 18/419,529, filed on Jan. 22, 2024.
(60) Provisional application No. 63/440,690, filed on Jan. 23, 2023.

(51) Int. Cl. C25B 11/036; B22F 1/105; B22F 3/10; B22F 3/16; B22F 9/02; B22F 9/04; C23C 14/02; C23C 14/06; C23C 14/08; C23C 24/10; C25B 9/75; C25B 9/77; C25B 11/032; C25B 11/063; C25B 11/081; C25B 11/089; C25D 3/56; C25D 5/18

(52) U.S. Cl. CPC C25B 11/036; C23C 14/021; C23C 14/0676; C23C 14/08; C23C 24/103; C25B 9/75; C25B 9/77; C25B 11/032; C25B 11/063; C25B 11/081; C25B 11/089; B22F 1/105; B22F 3/10; B22F 3/16; B22F 9/026; B22F 9/04; B22F 2009/043; B22F 2301/15; B22F 2301/205; B22F 2301/25; B22F 2302/45; B22F 2998/10; C25D 3/562; C25D 3/567; C25D 5/18

(57) ABSTRACT

An electrolyser system and method of electrode manufacture. The system for electrolyzing a solution comprises: a first vessel in communication with at least one electrolyser stack comprising: at least one bipolar electrode comprising: a bipolar plate; a porous transport layer; and a catalyst comprising a binder; the bipolar plate, the porous transport layer, and the catalyst fused together into a single component; at least one separator; and a second vessel in communication with the at least one electrolyser stack. A method for manufacturing a catalyst comprising a binder, the method comprising: contacting a primary element with a secondary element to form a binder material; contacting the binder material with a primary catalyst material to form a binder material and primary catalyst material mixture; and sintering the binder material and primary catalyst material mixture. A composition comprising: a primary catalyst; and a binder.

### CROSS-REFERENCE TO RELATED APPLICATIONS

This application is a continuation-in-part application of U.S. patent application Ser. No. 18/419,529, entitled “ELECTROLYSER SYSTEM AND METHOD OF ELECTRODE MANUFACTURE”, filed on Jan. 22, 2024, which claims priority and the benefit of U.S. Provisional Application No. 63/440,690, entitled “ELECTROLYSER SYSTEM AND METHOD OF ELECTRODE MANUFACTURE” filed on Jan. 23, 2023, and the specification and claims thereof are incorporated herein by reference in their entirety.

### FIELD OF THE INVENTION

This invention relates to the field of electrochemistry, specifically to the manufacturing and composition of electrodes for an ion exchange membrane and alkaline electrolysis technologies.

### BACKGROUND OF THE INVENTION

Hydrogen is an important part of any discussion on sustainability and emission reduction across major energy sectors. In addition to being a feedstock and process gas for many industrial processes, hydrogen is emerging as a fuel alternative for transportation applications. Renewable sources of hydrogen are therefore required to increase in capacity. Low-temperature electrolysis of water is currently the most mature method for carbon-free hydrogen generation and is reaching relevant scales to impact the energy landscape. However, costs for the low-temperature electrolysis of water still need to be reduced to be economical with traditional sources for the production of hydrogen. Operating cost reductions are enabled by the availability of low-cost sources of renewable energy, and the potential exists for a large reduction in capital cost with material and manufacturing optimization.

Challenges concerning hydrogen production by means of electrolyser systems include electrolyser system stability and the high cost of the electrode materials. Research efforts aiming to improve the electrocatalytic activity of platinum group metals (PGM) based catalysts are underway. Other research efforts involve the reduction of the amount of PGMs loading or elimination of PGMs altogether by developing a non-PGM electrode catalyst.

Electrodes used in AEM and alkaline technologies are critical for the performance of electrochemical devices such as fuel cells and electrolyzers. The efficiency of these devices is highly dependent on the surface area and catalytic activity of the electrode materials. Traditional sintering processes often lead to the agglomeration and loss of nano features, reducing the effective surface area and catalytic performance.

What is needed is a way to reduce the electricity burden for producing hydrogen and to reduce the cost of electrode materials while maintaining or increasing their efficacy. What is further needed is a way to reduce the sintering temperature and preserve the nano features of the catalyst materials to improve the electrode efficiency.

### BRIEF SUMMARY OF EMBODIMENTS OF THE PRESENT INVENTION

Embodiments of the present invention relate to a system for electrolyzing a solution comprising: a first vessel in communication with at least one electrolyser stack comprising: at least one bipolar electrode comprising: a bipolar plate; a porous transport layer; and a catalyst comprising a binder; the bipolar plate, the porous transport layer, and the catalyst fused together into a single component; at least one separator; and a second vessel in communication with the at least one electrolyser stack. In another embodiment, the system further comprises a substrate. In another embodiment, the substrate supports said catalyst. In another embodiment, the substrate comprises an alloying material. In another embodiment, the binder comprises a primary element. In another embodiment, the primary element comprises nickel. In another embodiment the binder comprises a secondary element. In another embodiment the secondary element comprises phosphorous. In another embodiment the binder is nickel-phosphorous.

Embodiments of the present invention also relate to a method for manufacturing a catalyst comprising a binder, the method comprising: contacting a primary element with a secondary element to form a binder material; contacting the binder material with a primary catalyst material to form a binder material and primary catalyst material mixture; and sintering the binder material and primary catalyst material mixture. In another embodiment the primary element comprises nickel. In another embodiment the secondary element comprises phosphorous.

Embodiments of the present invention also relate to a composition comprising: a primary catalyst; and a binder. In another embodiment the primary catalyst comprises a nickel alloy. In another embodiment the primary catalyst comprises a cobalt alloy. In another embodiment the primary catalyst comprises a transition metal. In another embodiment the primary catalyst comprises a platinum group metal. In another embodiment the binder comprises nickel. In another embodiment the binder comprises phosphorous. Embodiments the composition is a sintered composition.

Objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE SEVERAL VIEWS OF THE DRAWINGS

The accompanying drawings, which are incorporated into and form a part of the specification, illustrate one or more embodiments of the present invention and, together with the description, serve to explain the principles of the invention. The drawings are only for the purpose of illustrating one or more embodiments of the invention and are not to be construed as limiting the invention. In the drawings:

FIG. 1 is a diagram showing an embodiment of an electrolyser system;

FIG. 2 is a diagram showing an embodiment of an electrolyser stack;

FIG. 3 is a diagram showing an embodiment of a single cell ion exchange electrolyser;

FIG. 4 is a diagram showing an embodiment of a bipolar plate;

FIG. 5A is a diagram showing an embodiment of an electrolyser cell with an applied magnetic field;

FIG. 5B is a graph showing the direction of the current flow and magnetic field in the electrolyser cell shown in FIG. 5A;

FIG. 6A is a diagram showing an embodiment of an arrangement of a photoelectrochemical system;

FIG. 6B is a diagram showing an embodiment of an arrangement of a photoelectrochemical system;

FIG. 7 is a process flow diagram of an embodiment of electrode manufacture using sputtering or electroplating;

FIG. 8 is a process flow diagram of an embodiment of electrode manufacture;

FIG. 9 is a series of graphs showing the initial performance and current density of a novel membrane electrode assembly (“MEA”) of the present invention compared to a commercially available MEA;

FIG. 10 is a series of graphs showing the initial performance and long-term stability of a novel MEA of the present invention compared to a commercially available MEA;

FIG. 11 is a series of graphs showing the impact of selective etching of scarifying and/or leaching a material from a cathode and anode;

FIG. 12 is a series of graphs showing the impact of thermally treating a cathode and anode;

FIG. 13 is a series of photographs showing the micro-porous structure formed by scarifying and/or leaching a material from a cathode and/or anode; and

FIG. 14 is a graph showing the long-term stability of a nitrogen-assisted electrolyser.

### DETAILED DESCRIPTION OF THE INVENTION

The present invention is an electrolyser system that may comprise a bipolar plate, a current collector, a separator, an electrode comprising a catalytic material and a micro-porous structure, and an MEA/ion exchange membrane.

The term “metal” or “metals” is defined in the specification, claims, and drawings as a compound, mixture, or substance comprising a metal atom. The term “metal” or “metals” includes, but is not limited to, a metal hydroxide, a metal oxide, a metal salt, an elemental metal, a metal ion, a non-ionic metal, a mineral, or a combination thereof.

The terms “catalyst” or “catalytic material” or “primary catalyst” shall be used interchangeably in the specification, claims, and drawings. The terms “separator” and “bipolar plate” shall be used interchangeably in the specification, claims, and drawings.

The term “leach” is defined in the specification and claims as a process used to liberate, extract, free, or remove a metal or metals from a material.

The terms “micro-porous” or “micro-structure” are defined in the specification, claims, and drawings as a material wherein at least a portion of the material comprises pores less than one millimeter in diameter.

The terms “nano-porous” or “nano-structure” are defined in the specification, claims, and drawings as a material wherein at least a portion of the material comprises pores less than one micron in diameter.

The terms “tank” or “vessel” are used interchangeably and are defined in the specification, claims, and drawings as any holder, chamber, container, receptable, and/or other object capable of containing a fluid. The terms shall encompass any holder, chamber, container, receptacle, and/or other object of suitable scale or material. For example, they may include a large acid-resistant tank or vessel for the commercial-scale electrolysis of water.

The term “platinum group metals” includes, but is not limited to, platinum, palladium, rhodium, ruthenium, iridium, osmium, or a combination thereof.

The electrolyser system may split water into hydrogen and oxygen or a nitrogen compound into hydrogen and nitrogen at a lower voltage compared to conventional electrolysers. The electrolyser system may have greater electrode or MEA efficiency and long-term stability compared to conventional electrolysers.

The electrolyser system may achieve high cell current density with reduced need of PGMs. Specially, the electrolyser system may require less PGMs compared to conventional electrolysers employing PEM technology and requiring no PGMs compared to conventional electrolyser employing AEM and AE technologies.

An electrolyser system employing nitrogen-assisted hydrogen production does not have any risk of explosion caused by mixing of O₂ and H₂ gases because there is no oxygen evolution. The performance stability of an electrolyser system employing nitrogen-assisted hydrogen production may be higher compared to conventional water splitting systems, especially with long-term operation. The substitution of anodic reaction at the anode of nitrogen with oxygen allows the electrolyser system to operate at reduced or zero voltage and avoids oxidation and corrosion of the anode due to the presence of oxygen, i.e., nitrogen evolution instead of oxygen evolution. An electrolyser system employing nitrogen-assisted hydrogen production may have a higher range of stability, e.g., at least over 100 hours of continued operation with a change in performance, compared to an electrolyser system employing water to evolve hydrogen.

The methods herein may be applicable to a wide range of catalyst materials, primary elements, and secondary elements. The method herein may be suitable for various AEM and alkaline electrolysis applications.

The electrolyser system may comprise a primary catalyst comprising a binder. The primary catalyst may comprise catalyst material and binder material sintered together. The binder may preserve the nano features of an electrode and/or increase the surface area and may enhance catalytic activity and/or improve the performance of the electrodes. The binder may lower the sintering temperature and may lower the energy consumption and overall cost of the catalyst and/or electrode manufacturing process.

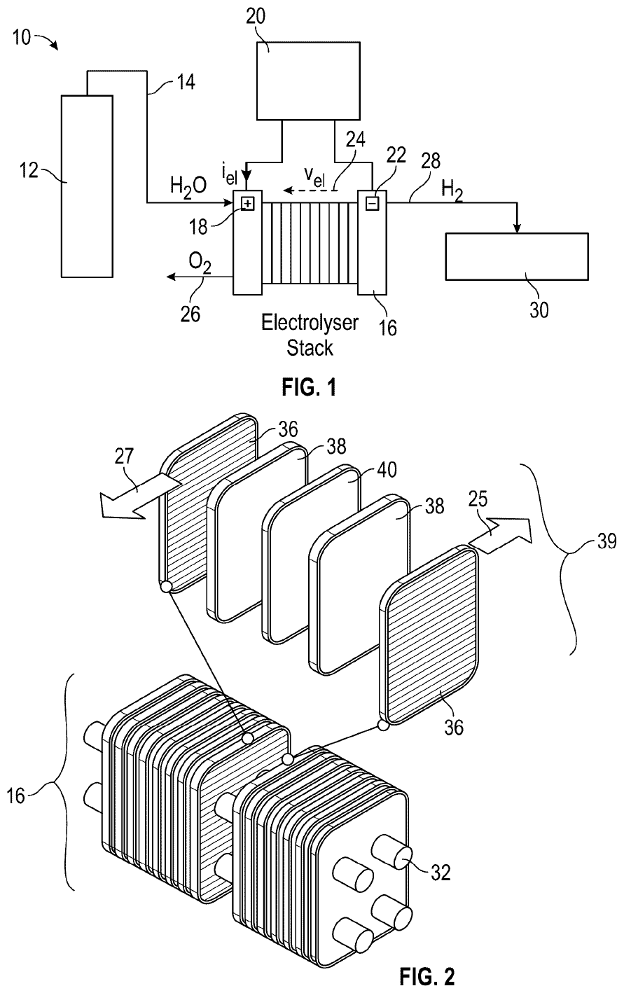

Turning now to the drawings, FIG. 1 shows electrolyser system 10. Water tank 12 may provide a water stream 14 to the positive-charge end 18 of electrolyser stack 16. Electrolyser stack 16 may be powered by power supply 20 connected to positive-charge end 18 and negative-charge end 22. Electrons may flow along path 24 within electrolyser stack 16 to split water into oxygen and hydrogen molecules. Oxygen may exit electrolyser stack 16 by outflow 26 and hydrogen may exit electrolyser stack 16 by outflow 28. Hydrogen may be collected in hydrogen storage tank 30.

FIG. 2 shows electrolyser stack 16 with an exploded view of single electrolyser cell 42. Individual electrolyser cells may be held together in a stack by connectors 32. Single electrolyser cell 34 may comprise electrodes 38 at least partially disposed between separators and/or bipolar plates 36. Membrane 40 may be at least partially disposed between electrodes 38. Hydrogen 27 and oxygen 25 may be produced at separators and/or bipolar plates 36 and may exit single electrolyser cell 34 at opposite sides of single electrolyser cell 34.

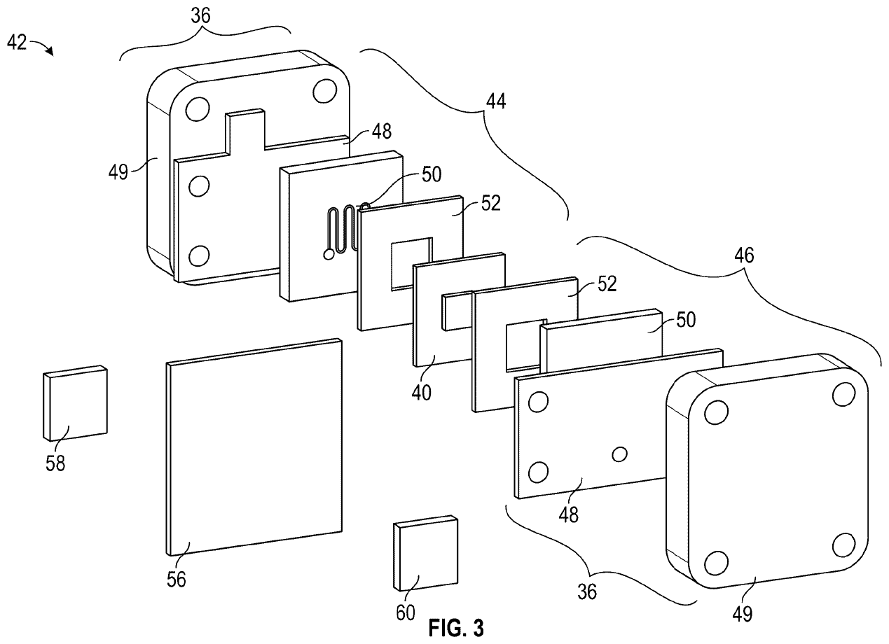

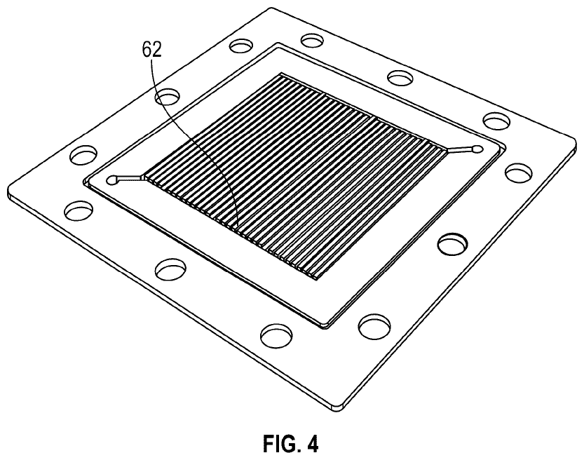

FIG. 3 shows a single cell ion exchange electrolyser 42. Membrane 40 may be at least partially disposed between gaskets 52. Membrane 40 may comprise ion exchange membrane 56, oxygen evolution reaction (“OER”) catalyst 58, and hydrogen evolution reaction (“HER”) catalyst 60. OER catalyst 58 and HER catalyst 60 may comprise a gas diffusion layer (“GDL”). Ion exchange membrane 56 may be at least partially disposed between OER catalyst 58 and HER catalyst 60. Gaskets 52 may be at least partially disposed between flow field plates 50. Flow field plates 50 may be at least partially disposed between separators and/or bipolar plates 36. Separator and/or bipolar plate 36 may comprise end plate 49 and current collector 48. Single cell ion exchange electrolyser 42 may comprise anode cell 44. Anode cell 44 may comprise separator and/or bipolar plate 36, flow field plate 50, gasket 52 and OER catalyst 58. Single cell ion exchange electrolyser 42 may comprise cathode cell 46. Cathode cell 46 may comprise separator and/or bipolar plate 36, flow field plate 50, gasket 52 and HER catalyst 60. FIG. 4 shows an embodiment of a separator and/or bipolar plate comprising serpentine channel pattern 62 that may be a component of single cell ion exchange electrolyser 42.

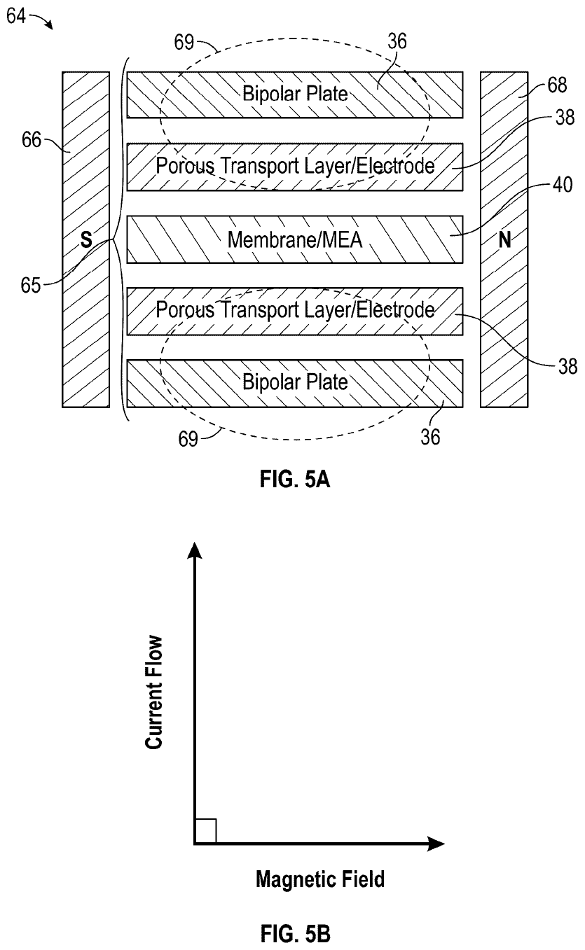

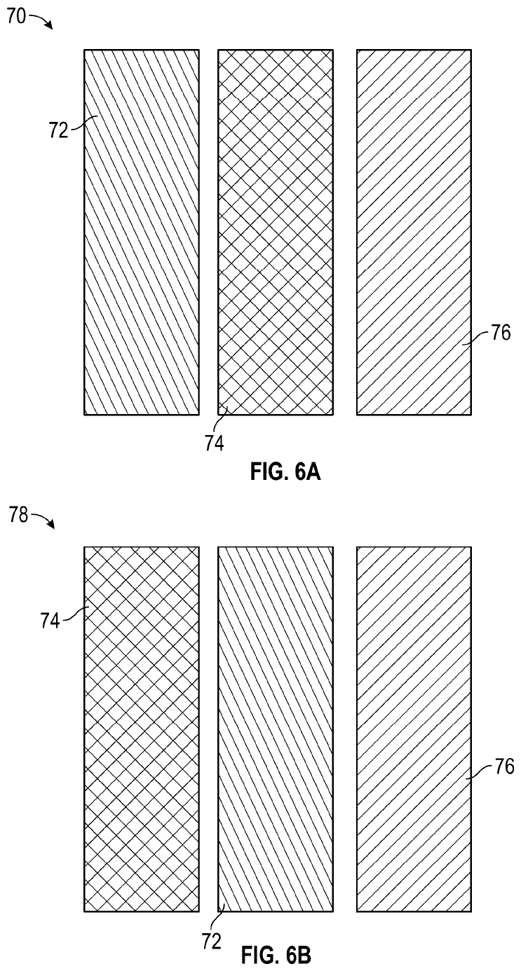

FIGS. 5A and 5B show an electrolyser cell with an applied magnetic field 64 and a graph showing the current flow and magnetic field in the electrolyser cell with an applied magnetic field 64. Cell assembly 65 may be at least partially disposed between south magnetic field end 66 and north magnetic field end 68. Cell assembly 65 may comprise separators and/or bipolar plates 36, electrodes 38, and membrane 40. Optionally, electrodes 38 may be replaced with a porous transport later and/or membrane 40 may be replaced with an MEA comprising a catalyst, a GDL, and electrodes 38. Magnetic fields 69 may be applied to separators and/or bipolar plates 36 and/or electrodes 38. A magnetic field may be applied parallel to south magnetic field end 66 and north magnetic field end 68 and a current flow may be applied perpendicular to the magnetic field. The current flow may traverse across and/or through at least one of the components of cell assembly 65.

FIGS. 6A and 6B show electrode arrangements photoelectrochemical system 70 and photoelectrochemical system 78. Photoelectrochemical system 70 comprises photo-cathode 74 at least partially disposed between photo-anode 72 and solar panel 76. Photoelectrochemical system 78 comprises photo-anode 72 at least partially disposed between photo-cathode 74 and solar panel 76. Solar panel 76 may convert solar radiation to electrical power and supply a voltage to photo-anode 72 and/or between photo-cathode 74. Optionally, photo-anode 72 and/or photo-cathode 74 may generate an electron flow by directly receiving solar radiation.

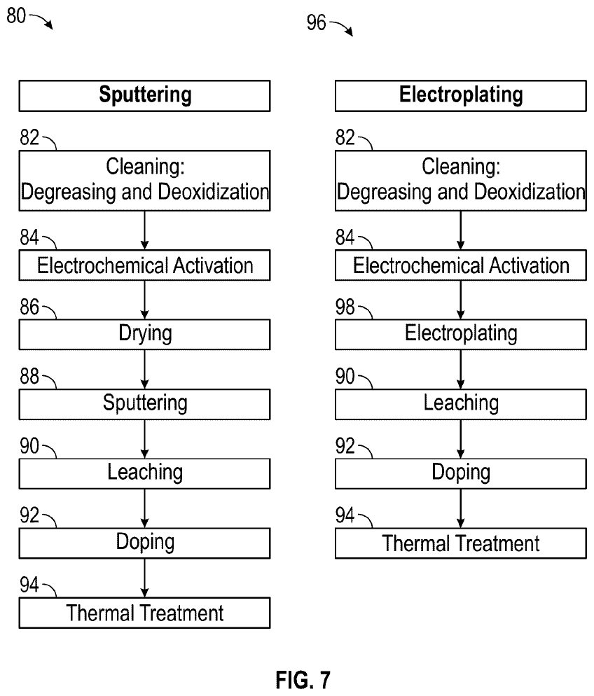

FIG. 7 shows an embodiment of electrode manufacturing using sputtering or electroplating. In sputtering manufacturing method 80, a substrate may be pre-treated by cleaning step 82. Cleaning step 82 may comprise degreasing and/or deoxidation. The substrate may then undergo electrochemical activation 84 by applying electric current. The activated substrate may undergo drying 86 following sputtering 88 of a compound comprising main and supporting materials. The supporting materials may comprise scarifying materials. The main and supporting materials may be subjected to leaching 90. Optionally, the scarified compound may undergo doping 92 to introduce a doping agent into the main material. The substrate with scarified compound may undergo thermal treatment 94.

In electroplating method 96, a substrate may be pre-treated by cleaning step 82. Cleaning step 82 may comprise degreasing and/or deoxidation. The substrate may then undergo electrochemical activation 84 by applying electric current. The activated substrate may undergo electroplating 98 of a compound comprising main and supporting materials. The supporting materials may comprise scarifying materials. The main and supporting materials may be subjected to leaching 90. Optionally, the scarified compound may undergo doping 92 to introduce a doping agent into the main material. The substrate with scarified compound may undergo thermal treatment 94.

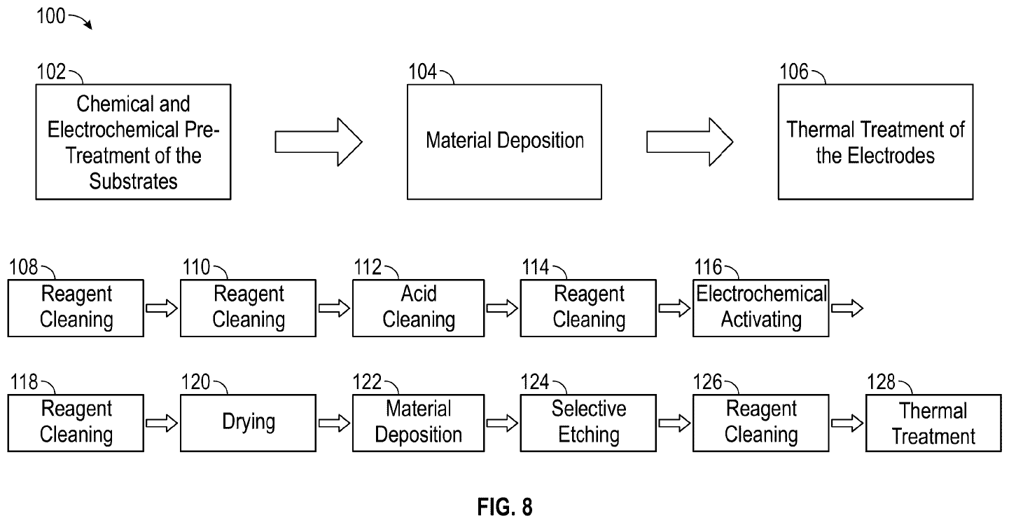

FIG. 8 shows electrode manufacture method 100. The electrode substrate may undergo chemical and electrochemical pre-treatment 102 followed by first material deposition 104. The substrate may then receive first thermal treatment 106 followed by first reagent cleaning 108 and second reagent cleaning 110. The water may comprise distilled and/or purified water. The substrate may then undergo acid cleaning 122 followed by third reagent cleaning 114. The substrate may then undergo electrochemical activation 116 followed by fourth reagent cleaning 118. The substrate may then be dried 120 and undergo second material deposition 122. The substrate with the deposited material may then be subjected to selective etching and/or leaching 124 followed by fifth reagent cleaning 126 and second thermal treatment 128. The reagent in any of the cleaning steps may comprise isopropyl alcohol, distilled water, purified water, acetone, ethanol, or a combination thereof.

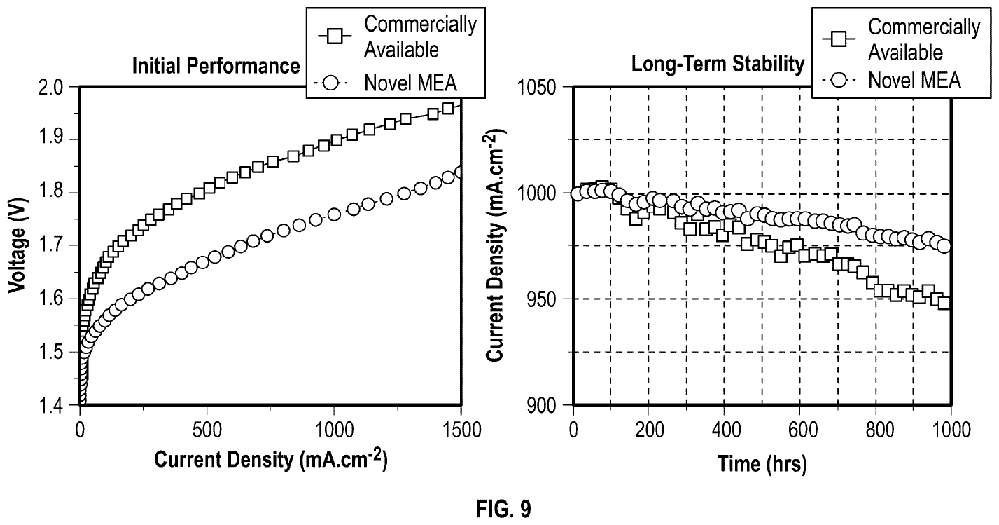

FIG. 9 shows a series of graphs comparing the initial performance and stability data of a commercially available MEA with the MEA of the present invention. The results demonstrate that the MEA of the present invention may achieve the same current density with less applied voltage compared to a commercially available MEA. The results also demonstrate that the MEA of the present invention have improved long-term stability compared to a commercially available MEA.

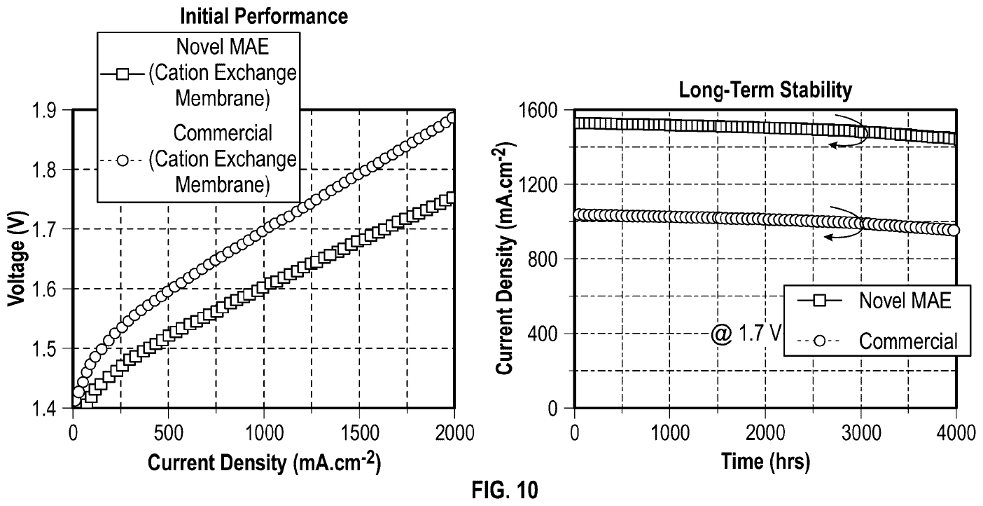

FIG. 10 shows a series of graphs showing the initial performance and current density of a novel electrode of the present invention compared to a commercially available electrode. The graphs compare the initial performance and stability data of a commercially available MEA incorporating a cation exchange membrane with the MEA of the present invention incorporating a cation exchange membrane. The cation exchange membrane is at least partially disposed between the anode and cathode compartments of the commercially available MEA and MEA of the present invention.

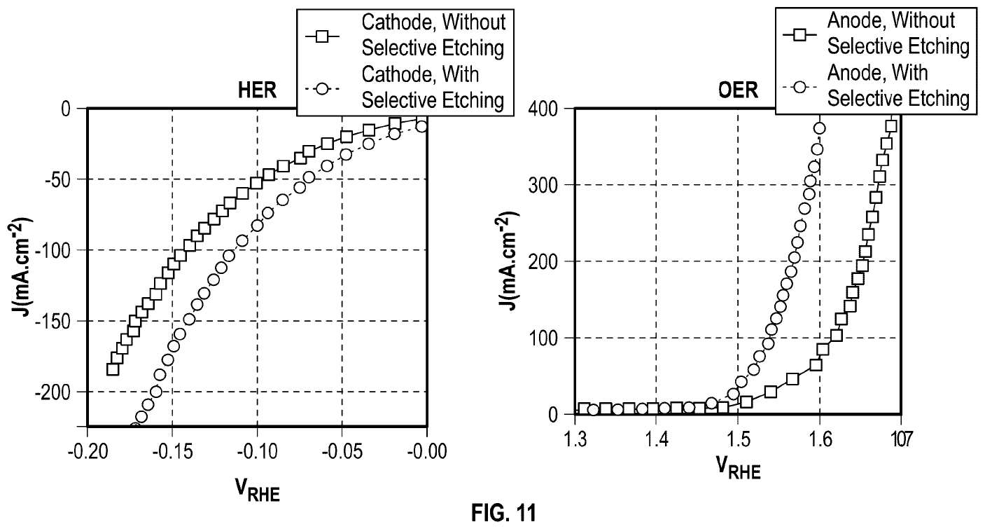

FIG. 11 shows the impact of selective etching of scarifying and/or leaching a material from a cathode and an anode. The graphs show the performance of a cathode without selective etching or leaching and with selective etching or leaching. The cathode with selective etching or leaching retained more energy compared to a cathode without selective etching or leaching for a given voltage. The graphs also show the performance of an anode without selective etching or leaching and with selective etching or leaching. The anode with selective etching or leaching retained more energy compared to an anode without selective etching or leaching for a given voltage.

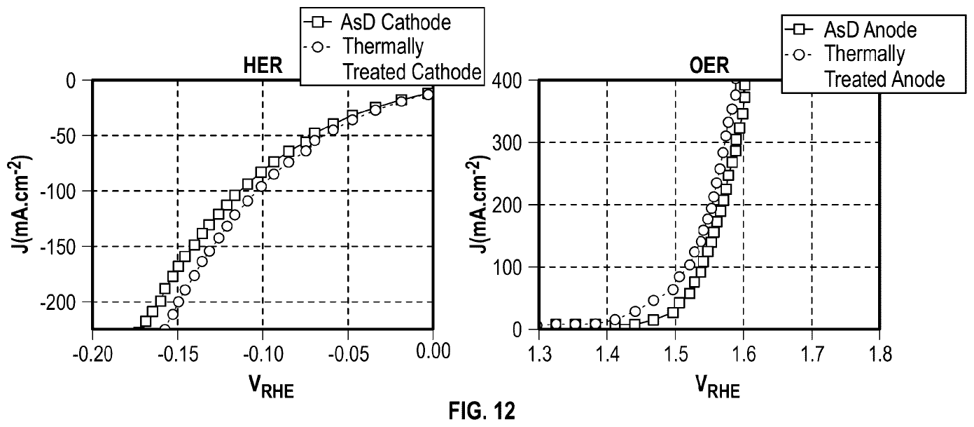

FIG. 12 shows the impact of thermally treating a cathode and anode. The graphs show the performance of a cathode and anode without thermal treatment and with thermal treatment. Thermal treatment increased the performance of the cathode and anode.

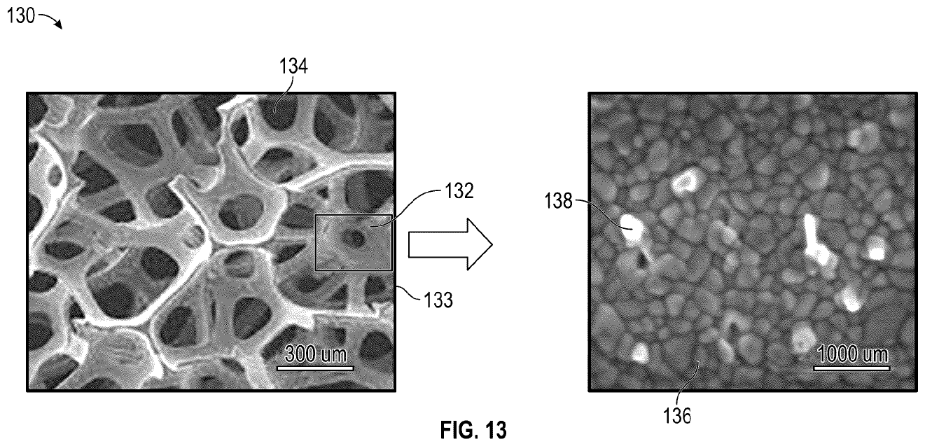

FIG. 13 shows the micro-porous structure formed by scarifying and/or leaching a material from a cathode and/or anode. Image series 130 shows pores 134 interspersed between scarified and/or leached material 132. Image series 130 also shows catalytic material 138 bound to substrate 136.

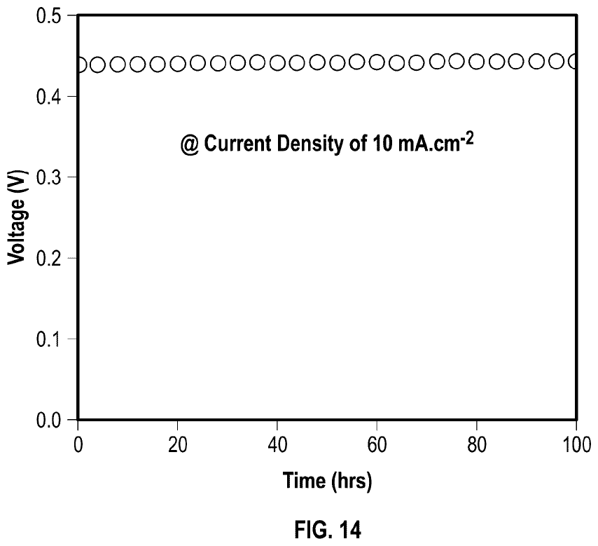

FIG. 14 shows the long-term stability of a two-electrode hydrazine electrolyser over 100 hours at current density 10 mA·cm⁻² in 1 M KOH and 0.2 M N₂H₄. The voltage was stable over the 100-hour period. The voltage remained approximately 0.45 V during the operation of the hydrazine electrolyser system.

The method may comprise reducing the sintering temperature by contacting a primary catalyst with a binder. Reducing the sintering temperature may preserve the nano features, e.g., pore size, porosity, gradient porosity, and/or increase the surface area of the electrode.

The system comprises a composition for a binder. The binder may comprise a primary element and a secondary element. The primary element may comprise a metal including, but not limited to, nickel, cobalt, iron, copper, zinc, or a combination thereof. The secondary element may comprise phosphorous, silica, arsenic, or a combination thereof. The binder may comprise, for example nickel-phosphorus (“NiP”). The binder may be contacted with the primary catalyst material and may be sintered together with the primary catalyst. The binder may reduce the sintering temperature, preserve the nano features of the catalyst, and increase the surface area of the electrode.

The incorporation of the binder including, but not limited to, NiP, may reduce the sintering temperature by lowering the activation energy required for sintering. The secondary element, e.g., phosphorous, may act as a fluxing agent and enhance diffusion processes at lower temperatures. High-temperature sintering typically leads to grain growth and agglomeration, resulting in a loss of nano features. Without being limited to a particular theory, lowering the sintering temperature may prevent grain growth and agglomeration. This may maintain high surface area and catalytic activity. Higher surface area may enhance catalytic activity and overall performance of the electrode and/or electrolyser system.

The method of making a catalyst comprising a binder may comprise contacting, e.g., ball milling, a primary element, e.g., a metal powder, with a secondary element to form binder material. The metal may comprise nickel (“Ni”), cobalt (“Co”), copper (“Cu”), zinc (“Zn”), or a combination thereof. The secondary element may comprise phosphorus (“P”), silicon (“Si”), arsenic (“As”), boron (“B”), or a combination thereof. The binder material may be at least about 1%, about 1% to about 15%, about 2% to about 14%, about 3% to about 13%, about 4% to about 12%, about 5% to about 11%, about 6% to about 10%, about 7% to about 9%, or about 15% secondary element by weight. However, the percentage of the secondary element may vary depending on the primary catalyst used and desired properties. The method may comprise mixing the binder material with primary catalyst material, e.g., cobalt, nickel, and/or PGM elements to form a catalyst and binder mixture. The primary catalyst materials may include, but are not limited to, nickel alloys, cobalt-based catalysts, and other transition metal catalysts or PGM group based materials. The catalyst and binder mixture may then be sintered. The sintering may occur at a significantly reduced temperature compared to traditional methods. The reduced sintering temperature may be at least about 5%, about 5% to about 30%, about 10% to about 25%, about 15% to about 20%, or about 30% less than traditional sintering temperatures. Traditional sintering temperatures may be in the range of about 500° C. to 1100° C.

The electrolyser system may comprise at least one electrolyser stack. The electrolyser stack may comprise at least one electrolysis cell. The electrolysis cell may comprise an anode cell and/or a cathode cell. The anode and/or cathode cell may comprise a bipolar plate, a flow field plate, a gasket, an electrode, a catalyst, or a combination thereof. A membrane may be disposed between the anode cell and cathode cell. The bipolar plate may comprise an end plate, a current collector, a flow channel, or a combination thereof and may be able to facilitate the conversing of gas dissolved in solution to gas. The flow field plate may comprise a flow field.

The electrolyser system may comprise a membrane. The membrane may comprise a proton-exchange membrane (“PEM”), an anion-exchange membrane (“AEM”), an alkaline electrolyser (“AE”) stack, or a combination thereof. The PEM and/or AEM may comprise PGMs. The PEM and AEM may be an ion exchange membrane. The electrolyser system may further comprise a cation exchange membrane including, but not limited to, Nafion 115, Nafion 117, Nafion 212, a perfluorosulfonic acid membrane, a polytetrafluoroethylene membrane, a chlor-alkali membrane, a carboxylic membrane, or a combination thereof. The electrolyser may achieve a high cell current density with an electrode comprising metal or mixed metal-metal oxide microstructures and/or nanostructures. The electrolyser may comprise a cathode and/or anode catalyst. The cathode and/or anode catalyst may comprise PGMs. A magnetic field may be externally applied to the electrolyser system including, but not limited to, the PEM, AEM, AE stack, electrode, catalyst, or a combination thereof. The electrolyser system may be a hydrogen electrolyser system. The membrane may comprise at least about 0.2 mg·cm⁻², about 0.2 mg·cm⁻² to about 3 mg·cm⁻², about 0.4 mg·cm⁻² to about 2.5 mg·cm⁻², about 0.6 mg·cm⁻² to about 2.0 mg·cm⁻², about 0.8 mg·cm⁻²to about 1.5 mg·cm⁻², about 1.0 mg·cm⁻² to about 1.2 mg·cm⁻², or about 3 mg·cm⁻².

The MEA may comprise AEM. The MEA may comprise a binder. The binder may comprise an anionic, cationic, or ionomer binder, or a combination thereof. The binder may be at least partially disposed between the anode and the AEM. A binder may also be at least partially disposed between the cathode and the AEM. The AEM may comprise an anionic and/or cationic exchange membrane. The binder may improve the ionic conductivity between the AEM and the anode and/or cathode by at least about 10%, about 10% to about 40%, about 15% to about 35%, about 20% to about 30%, or about 40%. The binder may comprise an ionomer and may comprise anionic or cationic properties. The binder may be at least partially disposed between the AEM and the corresponding anode or cathode in one of the following orders:
anode, first (anionic) binder, AEM, second (anionic) binder, cathode;
anode, first (cationic) binder, AEM, second (cationic) binder, cathode;
anode, first (anionic) binder, AEM, second (cationic) binder, cathode; or
anode, first (cationic) binder, AEM, second (anionic) binder, cathode.

The membrane of the MEA may comprise a PEM. The PEM may comprise a current density of less than about 4 A·cm⁻², about 0.5 A·cm⁻²to about 4 A·cm⁻², about 1 A·cm⁻² to about 3.5 A·cm⁻², about 1.5 A·cm⁻² to about 3 A·cm⁻², about 2 A·cm⁻² to about 2.5 A·cm⁻², or about 4 A·cm⁻². A cationic binder may be at least partially disposed between the anode and the PEM, and/or between the cathode and the PEM. The cationic binder may comprise an ionomer and may be prepared from an ionomer solution of at least about 5%, about 5% to about 20%, about 10% to about 15%, or about 20% wt % ionomer. In conventional PEM electrolyser technology, anode and cathode catalysts comprise PGMs. Platinum is mainly used for making cathodes and iridium and ruthenium are used for making anodes. The amount of platinum group materials used by conventional PEM electrolyser technology is typically between 1 to 3 mg/cm². An electrolyser system of the present invention comprising a PEM may comprise electrodes comprising at least about 0.01 mg/cm², about 0.01 mg/cm² to about 0.1 mg/cm², about 0.02 mg/cm² to about 0.09 mg/cm², about 0.03 mg/cm² to about 0.08 mg/cm², about 0.04 mg/cm² to about 0.07 mg/cm², about 0.05 mg/cm² to about 0.06 mg/cm², about 0.1 mg/cm² PGM without sacrificing performance. The PEM may also comprise a cationic membrane and/or cationic exchange membrane.

The electrolyser system may comprise a photoelectrochemical (“PEC”) system used for water splitting. The PEC system may comprise a transparent/semi-transparent photo-anode (PA), a transparent/semi-transparent photo-cathode (PC), a solar cell (SC), or a combination thereof. The PEC system may allow the generation of green hydrogen from sunlight and water with high solar-to-hydrogen efficiency, i.e., the yield of hydrogen gas is high compared to the amount of generated hydrogen by solar panel and electrolyser without a PEC system. The PEC system may comprise non-IIIV compound materials such as conductive metal oxide and perovskite materials.

The electrolyser system may comprise a solar panel as a power source. The solar panel may be incorporated into the PEC system to directly generate green hydrogen from sunlight and water with increased solar to hydrogen (STH) efficiency.

The photoanode may comprise an n-type semiconductor and/or perovskite material including, but not limited to, BiVO₄, TiO₂, WO₃, SrTiO₃, Fe₂O₃, ZnO, or a combination thereof. The n-type semiconductor and/or perovskite material which are used to form the heterostructure with a bandgap that may be transparent. Other compatible materials may also be simultaneously deposited during the deposition of anode materials to form high performance n-type semiconductors. ZnO and Ti or ZnO, Ti, and W may be deposited simultaneously to form a high-performance mixed oxide. The photoanode may also be coated by nanoparticles of anode catalyst including, but not limited to, a PGM- or Ni-based alloy to improve the overall performance of the photoanode.

A photocathode may comprise a p-type semiconductor and/or perovskite material including, but not limited to, copper based oxides, alloys of p-type metal oxides, or a combination thereof. P-type semiconductors and/or perovskite material may form the heterostructure with a bandgap that may be transparent. The photocathode may be coated with nanoparticles of cathode catalyst including, but not limited to, a PGM- or Ni-based alloy to improve the overall performance of the photocathode.

A photoelectrode, e.g., the photoanode and/or photocathode, may be manufactured to achieve a photocurrent density of more than 14 mA·cm ⁻² with a fill factor of more than 50%. A material in a photoelectrode may be optimized to achieve a crystalline structure. A crystalline structure may require the formation of a nanocrystal on the photoelectrode. The nanocrystal may be formed by tuning the deposition of material onto an electrode, for example by controlling the deposition time, deposition temperature, deposition pressure, controlling the reactant gas, or a combination thereof. The interface between the nanocrystal and electrode surface may also be optimized to integrate the nanocrystal into the photoelectrode. The interface may be optimized by controlling the deposition parameters of each material, for example by controlling the deposition time, deposition temperature, deposition pressure, controlling the reactant gas, deposition power, gas flow rate, or a combination thereof. Interfacial engineering may prevent changes in surface morphology and shape of the nanocrystal.

The photoanode and photocathode may be subsequently integrated with each other using sequential deposition. The integrated photoelectrodes may be directly integrated with a solar cell or a solar panel using physical and/or chemical deposition. Photoelectrode integration with a solar cell or panel may be performed by controlling the optical absorption of each photoelectrode or solar component so as to not interfere with the performance of the remaining photoelectrode or solar component. Optical absorption may be controlled by tuning the crystal quality and thickness of materials by adjusting the deposition parameters.

The STH efficiency of PEC systems may depend on the short-circuit photocurrent density, Faradaic efficiency for hydrogen evolution, and the incident illumination power density. All these parameters have to be measured under standard solar illumination conditions (AM 1.5 G solar spectrum). The STH efficiency may be measured according to Equation 1.

$$STH = \frac{2 \times {V}_{redux} \times {I}_{WE} \times {η}_{F}}{{P}_{in}} \qquad ( 1 )$$

STH efficiency may be calculated by multiplying two times the thermodynamic potential (V_{redox}), the electrolysis current (IWE) and the Faradaic efficiency for hydrogen evolution (ηF), then dividing by the input light power (Pin).

The PEC system may use non-III-V materials, which may affect the photocurrent density and hydrogen evolution, while achieving up to 30% STH efficiency. 30% STH efficiency is about three times greater than the STH efficiency achieved with conventional PEC technology.

The electrolyser system may comprise at least one electrolysis cell at least partially disposed between a pair of electromagnetic plates. The pair of electromagnetic plates may be arranged electromagnetically perpendicular to a current flow in the stack of electrolysis cells. The electromagnetic plates may generate a quasi-homogeneous magnetic field. The electromagnetic plates may accelerate collection of the hydrogen gas. Hydrogen gas acceleration may be accomplished by the coordinated effect of the quasi-homogenous magnetic field and the current flow of a charge carrier with the electrolyser stack. The charge carrier may comprise a proton.

The electrolyser system may produce hydrogen from a nitrogen compound in solution (nitrogen-assisted hydrogen production). Nitrogen-assisted hydrogen production may occur in a membrane electrolyser (either PEM or AEM), an alkaline electrolyser comprising a diaphragm to separate N₂ and H₂ gases, a membrane-free electrolyser, or combination thereof. The nitrogen-assisted hydrogen production may require contacting a nitrogen compound with the electrolyser. Nitrogen and hydrogen may be generated according to Equation 2 or 5, which are derived from the anodic half-reactions of Equation 3 and Equation 6, and the cathodic half-reactions of Equation 4 and Equation 7.

$$\begin{matrix}{N}_{2} {H}_{4} \to {N}_{2} + 2 {H}_{2} & {E}_{VS . SHE} = - 0.33 V\end{matrix} \qquad ( 2 )$$

$$\begin{matrix}Anode : {N}_{2} {H}_{4} + 4 O {H}^{-} \to {N}_{2} + 4 {H}_{2} O + 4 {e}^{-} & {E}_{VS . SHE} = - 1.16 V\end{matrix} \qquad ( 3 )$$

$$\begin{matrix}Cathode : 4 {H}_{2} O + 4 {e}^{-} \to 2 {H}_{2} + 4 O {H}^{-} & {E}_{VS . SHE} = - 0.83 V\end{matrix} \qquad ( 4 )$$

$$\begin{matrix}C {O ( N {H}_{2} )}_{2} + {H}_{2} O \to 3 {H}_{2} + {N}_{2} + C {O}_{2} & {E}_{VS . SHE} = + 0.37 V\end{matrix} \qquad ( 5 )$$

$$\begin{matrix}Anode : C {O ( N {H}_{2} )}_{2} + 6 O {H}^{-} \to {N}_{2} + C {O}_{2} + 5 {H}_{2} O + 6 {e}^{-} & {E}_{VS . SHE} = - 0.46 V\end{matrix} \qquad ( 6 )$$

$$\begin{matrix}Cathode : 6 {H}_{2} O + 6 {e}^{-} \to 3 {H}_{2} + 6 O {H}^{-} & {E}_{VS . SHE} = - 0 \text{.83} V\end{matrix} \qquad ( 7 )$$

The nitrogen compound may comprise hydrazine, urea and any other reagents can be decomposed to nitrogen upon dissolving into the electrolyte. Nitrogen-assisted hydrogen production may evolve nitrogen at an anodic site (e.g., the anode) instead of oxygen evolution. Nitrogen evolution may reduce the overall cell voltage and power required to operate the electrolyser system. The surface properties of the electrolyser system electrodes may be adjusted to shift the electrode electrochemical potentials. An electrolyser system splitting the nitrogen compound to evolve nitrogen and oxygen may be operated at an applied voltage of at least about 10 mV to about 1.5 V, about 50 mV to about 1.0 V, about 100 mV to about 0.8 V, about 0.2 V to about 0.6 V, or about 1.5 V. An electrolyser system employing nitrogen-assisted hydrogen production may operate without any applied voltage and/or produce electricity as a byproduct.

An electrolyser system employing nitrogen-assisted hydrogen production may comprise an electrolyte bath including, but not limited to hydrazine, urea, any other reagent that may be decomposed to nitrogen upon dissolving into the electrolyte, or a combination thereof; distilled water; an alkali metal electrolyte including, but not limited to, KOH, NaOH, K₂CO₃, or combination thereof; an acidic electrolyte including, but not limited to, H₂SO₄, H₂CO₃, or a combination thereof; or a combination thereof. The KOH may be at a concentration of at least about 1.0 M, about 1.0 M to about 5.0 M, about 1.5 M to about 4.5 M, about 2.0 M to about 4.0 M, about 2.5 M to about 3.5 M, or about 5.0 M. The hydrazine, urea, any other reagent that may be decomposed to nitrogen upon dissolving into the electrolyte, or a combination thereof, may be at a concentration of at least about 0.01 M, about 0.01 M to about 3.0 M, about 0.5 M to about 2.5 M, about 1.0 M to about 2.0 M, or about 3.0 M N₂H₄ or CO(NH₂)₂. The bath may be operated at a temperature of at least about 20° C., about 20° C. to about 80° C., about 25° C. to about 75° C., about 30° C. to about 70° C., about 35° C. to about 65° C., about 40° C. to about 60° C., about 45° C. to about 55° C., or about 80° C. An oxygen evolution reaction is prevented by the dominance of the nitrogen evolution reaction by controlling the concentration of nitrogen compound through a closed circulating bath and an auto dosing system. The risk of explosion caused by the mixture of H₂ and O₂ is removed.

The electrolyser system may comprise a power source. The power source may generate an alternating current, direct current, pulsed current, or a combination thereof. The power source may generate electrical energy from renewable energy sources including, but not limited to, solar radiation, thermal energy, tidal currents, wind power, bioenergy, or a combination thereof. The power source may transmit power, e.g., electric current, to an electrolyser cell of the electrolyser system. The electrical energy may be transmitted from the power source to the electrolyser system by means of at least one wire.

The electrolyser system may be operated at a temperature of at least about 20° C., about 20° C. to about 80° C., about 30° C. to about 70° C., about 40° C. to about 60° C., about 80° C. The operating temperature may preferably be about 60° C.

The electrolyser system may comprise an electrolyte. The electrolyte may comprise an alkaline electrolyte. The alkaline electrolyte may comprise an alkali metal including, but not limited to, lithium (“Li”), sodium (“Na”), potassium (“K”), rubidium (“Rb”), cesium (“Cs”), francium (“Fr”), or a combination thereof. The electrolyte may include, but is not limited to, KOH, K₂CO₃, NaOH, or a combination thereof. The electrolyte may be at a concentration of at least about 0.1 M, about 0.1 M to about 3 M, about 0.5 M to about 2.5 M, about 1.0 M to about 2.0 M, or about 3.0 M.

The MEA may be directly bonded to and/or at least partially disposed between a pair of electrodes. The pair of electrodes may comprise an anode and a cathode. The anode and the cathode may comprise a GDL and a catalyst in communication with the GDL. The catalyst may be attached to the GDL by physical or chemical deposition. The GDL may comprise a porous layer. Optionally, the anode and/or cathode may be GDLs with a catalyst coated on the surface of the anode and/or cathode. The GDL may comprise electrically conductive fiber, paper, foam, mesh, felt, or a combination thereof. The GDL may comprise a thickness of at least about 0.1 mm, about 0.1 mm to about 2 mm, about 0.2 mm to about 1.6 mm, about 0.4 mm to about 1.2 mm, about 0.6 mm to about 0.8 mm, or about 2 mm. The GDL may comprise a specific or variable porosity at least about 10%, about 10% to about 99%, about 20% to about 97%, about 30% to about 95%, about 40% to about 90%, about 50% to about 80%, about 60% to about 70%, or about 99%.

The electrode, e.g., cathode and/or anode, catalyst may be selected from a HER and/or OER volcano graph and may depend on the desired current density of the electrolyser system. The HER catalyst may include, but is not limited to, Mo, Nb, W, Co, Ni, Re, Rh, Pd, Pt, Ir, Au, Ag, Fe, Ti, Ta, Tl, Cu, Bi, Cd, Ga, or a combination thereof. The OER catalyst may include, but is not limited to, Cr, Ru, Mn, Fe, Ir, Co, Rh, Ni, Pt, Cu, Pt, Ag, Zn, Au, NbOx, ReOx, VOx, CrOx, SnObx, MoOx, MnOx, PtOx, IrOx, RuOx, TiOx, NiOx, PbObx, CoOx, or a combination thereof. The HER and/or OER may permit the electrolyser system, electrolysis cell, and/or electrode to operate at a current density of at least about 0.5 A·cm⁻², about 0.5 A·cm⁻² to about 2 A·cm⁻², about 0.75 A·cm⁻² to about 1.75 A·cm⁻², about 1 A·cm⁻² to about 1.5 A·cm⁻², or about 2 A·cm⁻²at a cell voltage of 1.8V. The cathode catalyst and anode catalyst may comprise a non-PGM selected from one of the following:
(Ni_{0.7±0.1}Fe_{0.3±0.1})_{α}X_{β}Y_{γ} where α+β+γ=100% (α being ≥50% and β and γ making up the remaining 50%, each ranging from 0-50%) and X and Y are selected from one of the following: Cr, Co, Mo, W, O, S, P, N;
(Al_{0.5±0.1})((Ni_{0.7±0.1}Fe_{0.3±0.1})_{α}X_{β}Y_{γ})_{0.5±0.1} where α+β+γ=100% (α being ≥50% and β and γ making up the remaining 50%, each ranging from 0-50%) and X and Y are selected from one of the following: Cr, Co, Mo, W, O, S, P, N, and where the catalyst is activated by leaching the aluminum to form pore-like structures; and
(Al_{0.5±0.1})(Ni_{0.7±0.1}Mo_{0.3±0.1})_{0.5±0.1}, where the catalyst is activated by leaching the aluminum to form pore-like structures and the current density is greater 2 A*cm⁻² at cell voltage of 1.8V.

The cathode catalyst may comprise a PGM selected from the following:
(Al_{0.5±0.1})(Mo_{0.7±0.1}Pt_{0.3±0.1})_{0.5±0.1}; and
Al_{0.7±0.1}Pt_{0.3±0.1}.

The anode catalyst may comprise a PGM activated by leaching the aluminum to form pore like structures selected from the following:
(Al_{0.5±0.1})(IrₓRu_{y})_{0.5+0.1};
An inner layer of (Ni_{0.7±0.1}Fe_{0.3±0.1})_{α}X_{β}Y_{γ} where α+β+γ=100% (α being ≥50% and β and γ making up the remaining 50%, each ranging from 0-50%) and X and Y are selected from one of the following: Cr, Co, Mo, W, O, S, P, N, and an outer layer of Al_{0.7+0.1}(IrOx)_{0.3±0.1};
An inner layer of (Ni_{0.7±0.1}Fe_{0.3±0.1})_{α}X_{β}Y_{γ} where α+β+γ=100% (α being ≥50% and β and γ making up the remaining 50%, each ranging from 0-50%) and X and Y are selected from one of the following: Cr, Co, Mo, W, O, S, P, N, and an outer layer of (Al_{0.5±0.1})(IrₓRu_{y})_{0.5+0.1}; and
(Ni_{0.7±0.1}Fe_{0.3+0.1})_{α}Al_{β} (where α+β+γ=100% (α being ≥50% and β and γ making up the remaining 50%, each ranging from 0-50).

The bipolar plate may comprise a gas and/or liquid flow channel. The gas and/or liquid flow channel may comprise a channel. The channel may include, but is not limited to, a serpentine, a column-pin, or a parallel or straight channel pattern, or a combination thereof. The bipolar plate may comprise a current collector, an electrolyte pressure and flow controller, electrical resistance regulator, or a combination thereof. A bipolar plate's channel pattern and the surface engineering of deposited materials onto these plates may affect the electrolyte pressure, electrolyte flow, and/or electrical resistance of the bipolar plate. A bipolar plate's channel pattern may comprise a defined depth, width, and curvature.

A bipolar plate's channel pattern may facilitate liquid and/or gas management within an electrolysis. Optimizing the bipolar plate may prevent gas from being trapped within the electrolyser system and may result in improved electrolyte flow within the electrolyser system and gas release from the electrolyser system. Optimizing the bipolar plate may be done by changing the pattern of gas and/or liquid flow channel to prevent gas from being trapped in the bipolar plate and/or electrolyser system, and by coating the bipolar plate with conductive and/or corrosion-resistant materials to avoid the oxidation and facilitate electrical conductivity. The bipolar plate may comprise nickel, stainless steel, titanium, carbon based products, and aluminum, plastic, acrylic, foam, or a combination thereof. The conductive corrosion resistant materials may comprise an alloy including, but not limited to, gold, silver, copper, aluminum, nickel, iron, molybdenum, chromium, niobium, ruthenium, rhodium, palladium, osmium, iridium, platinum, zinc, bronze, brass, or a combination thereof.

The electrolyser system may comprise an electrode manufactured by a sputtering or electroplating method. The electrode may be manufactured by first pre-treating a substrate. The substrate may include, but is not limited to, nickel, chromium iron, molybdenum, copper, titanium, steel, stainless steel, nickel-chromium alloy, nickel-iron alloy, nickel-molybdenum alloy, nickel-copper alloy, titanium alloy, felt, paper, foam or a combination thereof. The substrate may be cleaned and/or degreased to remove oil, grease, and/or native oxide from the substrate. The substrates may be cleaned and/or degreased by ultrasonic cleaning (resistivity of >18 Ω×cm) and/or contact with NaOH, acetone, ethanol, methanol, isopropyl alcohol, distilled water, or combination thereof. A substrate may be cleaned and/or degreased at least once for at least about 5 min, about 5 min to about 30 min, about 10 min to about 25 min, about 15 min to about 20, or about 30 min. Native oxide may be removed from the surface of the substrate by contacting the substrate with an acid. The substrate may be immersed in an acidic solution. The acid may include, but is not limited to, hydrochloric acid, hydrofluoric acid, sulfuric acid, or a combination thereof.

Optionally, the substrate may be contacted with etchant that may at least partially remove the native oxide from the substrate. The acid may be at a concentration of at least about 5%, about 5% to about 50%, about 10% to about 45%, about 15% to about 40%, about 20% to about 35%, about 25% to about 30% weight concentration in solution (w/w). The acid may be at temperature of at least about 50° C., about 50° C. to about 80° C., about 55° C. to about 75° C., about 60° C. to about 70° C., or about 80° C.

The substrate may be electrochemically activated by applying an electrical current to the substrate. The applied current density may be at least about 40 mA/cm², about 40 mA/cm² to about 1000 mA/cm², about 80 mA/cm² to about 900 mA/cm², about 100 mA/cm² to about 800 mA/cm², about 200 mA/cm² to about 700 mA/cm², about 300 mA/cm² to about 600 mA/cm², about 400 mA/cm² to about 500 mA/cm², or about 1000 mA/cm². The substrate may be activated by HCl immersion followed by acetone and/or deionized water wash and/or rinse.

Powder metallurgy (“PM”) techniques may be used to produce a substrate for the electrode in an electrolyser stack. The substrate may be a platform onto which a catalyst is applied. The substrate may be a conducting material including, but not limited to, a ferrous metal, alloy, or a combination thereof. The substrate may be electrically conductive, and comprise conductive metals including, but not limited to, nickel, titanium, stainless steel, or a combination thereof. This substrate may operate in a chemical environment created in the electrolyser stack. The substrate may include, but is not limited to, nickel, iron, molybdenum, cobalt, titanium, tantalum, graphite, aluminum, tungsten, copper, silver, gold, platinum group metals, or a combination thereof. An alloying metal may also be present to tailor the properties of the substrate. The alloying metals may include, but are not limited to, zinc, tin, lead, or a combination thereof. The substrate may comprise ceramic components, transition metal oxides, a catalytically active material, or a combination thereof. The catalytically active material may include, but is not limited to, iridium, platinum, molybdenum, titanium, tungsten, cobalt, nickel, niobium, palladium, ruthenium, rhenium, tantalum, bismuth, strontium, lanthanum, vanadium, indium, gold, silver, iron, copper, magnesium, zinc, chrome, nitride, or oxide, phosphide and sulfide of the above mentioned materials, or a combination thereof. Any combination of the catalytically active materials may assist in the catalytic process.

Ceramic and/or metal powders may be combined by mixing or milling precursor powders together in either the dry or wet state. In the dry state, powders may be blended with a solid lubricant and binding agent. In the wet state, a binder, lubricant, plasticizer, surfactant, or a combination thereof may be combined with a suitable carrier fluid with up to 60 vol % solids loading to produce a slurry. The carrier fluid may include, but is not limited to, alcohol, ethanol, water, acetone, or a combination thereof. The carrier fluid may comprise a solids loading of at least about 10 vol %, about 10 vol % to about 75 vol %, about 20 vol % to about 60 vol %, about 30 vol % to about 50 vol %, or about 75 vol %. The slurry may comprise a viscosity of at least about 50 mPa·S, about 50 mPa·S to about 4500 mPa·S, about 100 mPa·S to about 4250 mPa·S, about 150 mPa·S to about 4000 mPa·S, about 200 mPa·S to about 3750 mPa·S, about 300 mPa·S to about 3500 mPa·S, about 400 mPa·S to about 3250 mPa·S, about 500 mPa·S to about 3000 mPa·S, about 750 mPa·S to about 2500 mPa·S, about 1000 mPa·S to about 2250 mPa·S, about 1000 mPa·S to about 2000 mPa·S, about 1250 mPa·S to about 1750 mPa·S, or about 4500 mPa·S. The viscosity may depend on the fabrication technique. Mechanical alloying may also be used to produce an alloy material by mechanically combining the metals mentioned above. Other fabrication techniques may include, but are not limited to, spray drying, freeze drying, powder tumbling, spheroidization methods, sieving, screen cutting, or a combination thereof. A fabrication technique may be followed by tablet compaction into a “green” compact. Additional fabrication techniques may include, but are not limited to, gel casting, tape casting, extrusion of substrate materials, or a combination thereof.

The fabrication of the substrate may comprise powder compaction wherein a compressed sheet may comprise a thickness at least about 75 μm, about 75 μm to about 2500 μm, about 100 μm to about 2000 μm, about 200 μm to about 1800 μm, about 400 μm to about 1600 μm, about 600 μm to about 1400 μm, about 800 μm to about 1200μm, or about 2500 μm. The compressed sheet may comprise pressed and/or compacted powder agglomerates bound together by a polymer matrix. The compressed sheet with pressed and/or compacted powder agglomerates forms a green compact. The green compact may then be sintered by subjecting it to a binder burnout step followed by partial sintering to retain the porous structure left behind by the incomplete compaction process and the burnt-out polymer binder. Another method may use extrusion or casting of a slurry to produce a tape or film which is then subject to the binder burnout and sintering process. The tape or film thickness for this method may be at least about 1 μm, about 1 μm to about 2000 μm, about 10 μm to about 1800 μm, about 50 μm to about 1600 μm, about 75 μm to about 1400 μm, about 100 μm to about 1200 μm, about 200 μm to about 1000 μm, about 300 μm to about 800 μm, about 400 μm to about 700 μm, about 500 μm to about 600 μm, or about 2000 μm. The tape or file may be single or multi-layered.

The sintering process may be performed under vacuum or in the presence of inert gases including, but not limited to, argon, helium, or a combination thereof. The sintering process may also be performed in the presence of other gases including, but not limited to, nitrogen, methane, hydrogen, sulphur-containing gases like H₂S and SO₂,or a combination thereof. The sintering process may produce the desired microstructure and functional gradients within the PM substrate to form a sintered porous structure. A functional gradient is a region of varying material properties across a material and may comprise a density variation, composition change but usually both across the depth of the substrate material. Sintering and PM fabrication may produce a highly porous region. The highly porous region may comprise a porosity of at least about 20%, about 20% to about 95% porosity, about 25% to about 90%, about 30% to about 85%, about 35% to about 80%, about 40% to about 75%, about 45% to about 70%, about 50% to about 65%, about 55% to about 60%. The porous region may act as a substrate for the catalyst.

Contact resistance between the bipolar plates, porous transport layers (“PTL”) and catalyst may determine the performance of the electrolyser stack. An all-in-one single unit of “bipolar electrodes” may be created by fusing together the bipolar plate, PTL and catalyst to form a single-piece component that may eliminate the contact resistivity between the components of the electrolyser stack. The bipolar plate may increase the efficiency and long-term stability of the electrolyser stack. Compared to current technology for the anion exchange membrane electrolyser or fuel cell and the proton exchange membrane electrolyser or fuel cell, there is a mechanical connection between the porous transport layers and bipolar plate. Furthermore, catalyst particles are loosely connected to each other through the ionomer leading to high contact resistance and extremely low utilization of catalyst due to deactivation of some part of the catalyst.

The bipolar plate may increase mechanical contact between the electrolyser stack components and may increase the mass transport, activation, and ohmic resistance of the electrolyser stack. The increased mechanical contact may result in enhanced over potential and prevent the decline of the long-term stability by eliminating contact resistance. In our proposed technology the bipolar plate and electrodes may be sintered together at high temperature, ranging from at least about 500° C., about 500° C. to about 1100° C., about 600° C. to about 1000° C., about 700° C. to about 900° C., or about 1100° C. The sintering may be performed in the presence of a gas including, but not limited to, argon, nitrogen, hydrogen, oxygen, sulfur, phosphide, or a combination thereof. The sintering may also be performed under vacuum or in the presence of ambient air. Sintering the bipolar plate may allow porous transport layers and catalysts to operate with improved efficiency. Sintering the bipolar plate may allow the bipolar plate porous transport layer and the electrode and/or catalyst to be fused together as a single component and operate as a single electrolyser piece.

Sputtering or electrodeposition may be used to apply a material to a substrate. A substrate may undergo drying if sputtering is used to apply material. The drying may comprise nitrogen drying. Optionally, drying may be carried out by vacuum oven at a temperature range of at least about 60° C., about 60° C. to about 250° C., about 80° C. to about 230° C., about 100° C. to about 210° C., about 120° C. to about 190° C., about 130° C. to about 170° C., or about 250° C. The substrate may be dried completely. A substrate may be rinsed with solvent if electroplating is used to apply material. The solvent may comprise distilled and/or purified water.

A material may be deposited onto the surface of an electrode substrate. The material may comprise a compound material. The compound material may be deposited onto the surface of the substrate by physical deposition including, but not limited to, sputtering, e-beam evaporation, or a combination thereof; or chemical deposition including, but not limited to, electroplating, electrochemical deposition, or a combination thereof. The compound materials may comprise a main material and a supporting material. The main material may comprise a catalyst. The catalyst may include, but is not limited to Ir, Pt, Ru, Re, Pd, Ni, Fe, Mo, Cr, W, Ti, Co; an alloy of Ir, Pt, Ru, Re, Pd, Ni, Fe, Mo, Cr, W, Ti, Co; or a combination thereof. The compound material may include, but is not limited to, NiPt, NiIr, NiRu, PtIr, PtRu, IrRu, IrW, IrTi, IrPd, or a combination thereof. The supporting material may comprise a scarifying material and a doping agent.

The scarifying material may include, but is not limited to Li, Ca, Na, Al, Mg, Zn, or a combination thereof. The scarifying material may comprise a lower electrochemical potential as compared to the main catalyst. The main material and supporting material may be simultaneously deposited onto the substrate. The amount of main and supporting material deposited onto the substrate may be at least 25% the weight of the substrate. The scarifying material may be late leached out of the compound material by selective etching. An etchant, or etching method, may be used to selectively etch and/or leach the scarifying material. Negligible etching and/or etching of the main material may occur during the leaching and/or selective etching process. The main material and the scarifying material may be deposited at the same time using either physical and/or chemical deposition methods.

Simultaneous deposition of the main and scarifying material may be done by using a compound target and/or a compound target precursor, or multi target and/or a multitarget precursor of the material if a physical deposition method is employed. The compound and/or multi target may depend on the physical deposition method. A precursor may be an atom, e.g., Pt, Ni, etc., in a compound and/or multi target. Selection of the appropriate target or precursor may allow the compound material to be deposited, i.e., bound, onto the substrate. For example, a sputtering target may be used if a compound material is deposited by a sputtering method. The sputtering target may be a single material including, but not limited to, Pt, Ni, or combination thereof and/or a combination of materials including, but not limited to, NiPt, NiMo, NiPtIr, or a combination. The target or compound target may be specific to the method. For example, a precursor may be used instead of a compound or multi target if ebeam evaporation is used to deposit the compound material onto the substrate. A mixed salt compound or salt of compound material may be used to apply the compound material to the substrate using a chemical deposition method. The salt may include, but is not limited to, NiCl₂·6H₂O, FeCl₂·4H₂O, CoCl2·6H₂O, (NH₄)₂MoO₄, ZnCl₂, T/H₂PtCl₆, CoCl2·6H₂O, Ti/IrCl₄·H₂O, ZnCl₂, or a combination thereof. A pulse current wave may be used when applying the compound material with an electrochemical deposition. The pulse wave may range from at least about 50 [symbol] S, about 50 (S to about 5000 [symbol] S, about 100 [symbol] S to about 4500 [symbol] S, about 200 [symbol] S to about 4000 [symbol] S, about 300 [symbol] S to about 3500 [symbol] S, about 400 [symbol] S to about 3000 [symbol] S, about 500 [symbol] S to about 2500 [symbol] S, about 600 [symbol] S to about 2000 [symbol] S, about 700 [symbol] S to about 1500 [symbol] S, about 800 [symbol] S to about 1000 [symbol] S, or about 5000 [symbol] S for tₒₙ. The pulse wave may also range from at least about 10 [symbol] S, about 10 [symbol] S to about 1000 [symbol] S, about 100 [symbol] S to about 900 [symbol] S, about 200 [symbol] S to about 800 [symbol] S, about 300 [symbol] S to about 700 S about, 400 [symbol] S to about 600 [symbol] S, or about 1000 [symbol] S for t_{off}. Each compound material can be deposited separately and simultaneously to reach targeted composition, i.e., simultaneous co-deposition of the main and the supporting material onto the substrate. Simultaneous deposition allows the formation of alloys and electrodes using up to ten times less PGM group materials while showing a higher degree of catalytic activity compared to a conventional electrode. The electrode's catalyst activity relates to the surface of active area. Leaching and/or selectively etching the scarifying material results in the formation of a micro-porous and/or nano-porous structure within the electrode. The scarifying materials that are leached and/or selectively etched leave pores within the compound material. The formation of the micro-porous and/or nano-porous structure increases the exposed surface area and/or active area of the catalyst material. The increased surface area increases the catalytic activity of the electrode while reducing the amount of the catalytic material required to manufacture the electrode. The active area may be increased by at least about 30%, about 30% to about 150%, about 40% to about 125%, about 50% to about 100%, about 60% to about 75%, or about 150%. The surface area of the catalyst may be increased by at least about 10%, about 10% to about 75%, about 20% to about 70%, about 30% to about 60%, about 40% to about 50%, or about 75%.

Leaching and/or selectively etching the scarifying material may form micro-and/or nano-pores in the compound material. The porous compound material may form the micro-porous and/or nano-porous structure of the electrode. The pore diameter in the nano-porous structure may be about the width of the leached and/or selectively etched atom such that the pore diameter is wide enough to receive the leached and/or selectively etched atom. For example, in a compound material comprising NiPt, the Ni atom would be leached and/or selectively etched from the NiPt compound to form a nano-porous structure comprising nanopores. The nanopores would comprise a diameter sufficient to receive the Ni atom.

The supporting material may comprise a doping agent including, but not limited to, nitrogen, phosphorous, sulfur, boron, molybdenum, iron, chromium, cobalt, copper, or a combination thereof. The support material may comprise a doping compound including, but not limited to, an oxynitride; a nitrogen and sulfur compound; a nitrogen and phosphorous compound; a nitrogen and boron compound; a nitrogen and molybdenum compound; a nitrogen and iron compound; or a combination thereof. A doping may be introduced into the main compound as a trace of impurity to alter a surface property of the electrode including, but not limited to, an electrical property or electrochemical potential. A doping agent may be present in a main material in a trace amount, i.e., less than 5%. A doping agent may comprise a different atomic size and configuration compared to the main compound, that is why it is called impurity. Doping may be conducted within or after deposition of the compound material. The doped material may comprise a reduced cell potential compared to the theoretical minimum value of 1.23V to less than zero, depending on the doping material and its concentration. Lowering a cell potential allows less power to be applied to a cell, thereby improving the overall efficiency of the electrolyser. A doping agent may improve the electrolyser system's efficiency by at least about 10%, about 10% to about 80%, about 20% to about 70%, about 30% to about 60%, about 40% to about 50%, or about 80%.

An electrode surface property may be tailored to have the minimum required potential and/or maximum efficiency by applying a doping agent to the electrode. The doping agent may be added to the electrode by co-deposition in sputtered compound material; employing a reactive gas during sputtering; electrochemical and/or thermochemical addition following leaching and/or selective etching; or a combination thereof. In co-deposition method, the doping agent may be simultaneously deposited onto the electrode along with the other components of the compound material. The doping agent may be less than 10% of the compound material. In the reactive gas method, the ratio of nitrogen gas to argon gas may be less than about 30%, to diffuse the doping agent, e.g., nitrogen, into the electrode simultaneously with the deposition of main material. With electrochemical doping, the doping agents, which may include, but are not limited to, N, P, S, and/or B, may be dissolved/dispersed into an electrolyte solution. The doping agent may be incorporated into the electrode and/or compound material by applying an electrical potential to the electrolyte solution. The electrical potential may be at least about 50 mV, about 50 mV to about 1500 mV, about 100 mV to about 1300 mV, about 200 mV to about 1100 mV, about 300 mV to about 900 mV, about 500 mV to about 700 mV, or about 1500 mV. With thermochemical doping, the compound material and doping agent may be disposed within an inert gas-filled furnace, e.g., under an argon atmosphere. The doping agent may be mounted, diffused into and/or added into the compound material by increasing the temperature. The temperature may be increased to at least about 250° C., about 250° C. to 900° C., about 300° C. to 800° C., about 400° C. to 700° C., about 500° C. to 600° C., or about 900° C. to dope the compound material with the doping agent. For all methods, the doped electrode may be treated by a reagent including, but not limited to, potassium hydroxide (KOH), K—Na-tartrate-tetrahydrate, or a combination thereof, followed by deionized water cleaning, nitrogen drying, oven drying, or a combination thereof to form a micro-porous and/or nano-porous structure. Additionally, for all methods, the doping agent may be embedded, doped, and/or added into the supporting material of the compound material.

Different types of etching methods may be employed including, but not limited to, physical etching, including but not limited to, reactive ion etching (RIE) and inductively coupled plasma etching; or chemical/electrochemical etching to leach the scarifying material. Etching requires contacting the scarifying material with a substance to remove it. One or more gases may be used as the etchant in physical etching. A reagent may be used for chemical/electrochemical etching. An electrode may be etched by immersion into a bath comprising a chemical/electrochemical etchant. Bath composition, working temperature, time, and applied current may vary depending on the selected material for etching.

A bath for chemical/electrochemical etching may comprise basic or acidic solutions including, but not limited to, KOH, NaOH, HCl, H₂SO₄, or a combination thereof. The bath may also comprise an additive including, but not limited to, a buffer, hydrazine, a scaling inhibitor, an etching facilitator, or a combination thereof. The buffer may include, but is not limited to, boric acid, borate, or a combination thereof, may be used to maintain bath pH. Hydrazine may be used to prevent oxidation in bath with low pH values. A scaling inhibitor including, but not limited to, a polyphosphate, may prevent precipitation of salts on the electrode while etching. An etching facilitator including, but not limited to, potassium-sodium-tartrate-tetrahydrate, may accelerate etching in alkaline environments. The bath may be operated at a temperature of at least about 25° C., about 25° C. to about 85° C., about 30° C. to about 80° C., about 35° C. to about 75° C., about 40° C. to about 70° C., about 45° C. to about 65° C., about 50° C. to about 60° C., or about 85° C. A current may be applied to the bath. The current may comprise a direct current, alternating current, pulsed current, or a combination thereof. An applied direct current may be at least about 25 mA/Cm², about 25 mA/Cm² to about 1000 mA/Cm², about 50 mA/Cm² to about 900 mA/Cm², about 100 mA/Cm² to about 800 mA/Cm², about 200 mA/Cm² to about 700 mA/Cm², about 300 mA/Cm² to about 600 mA/Cm², about 400 mA/Cm² to about 500 mA/Cm², or about 1000 mA/Cm².

The electrolyser system may comprise at least one electrode. The electrode may comprise an anode and/or cathode. The electrode may be thermally treated to improve performance. A vacuum thermal treatment may be applied to an electrode. The vacuum thermal treatment may be operated at a temperature of at least about 300° C., about 300° C. to about 1000° C., about 400° C. to about 900° C., about 500° C. to about 800° C., about 600° C. to about 700° C., or about 1000° C. The vacuum thermal treatment may be operated for at least about 30 min, about 30 min to about 4 hours, about 1 hour to about 3.5 hours, about 1.5 hours to about 3 hours, about 2 hours to about 2.5 hours, or about 4 hours. Thermal treatment may comprise increasing the temperature of the electrode, maintaining the temperature of the electrode, and reducing the temperature of the electrode. Increasing and decreasing the electrode temperature may be performed at a rate of at least about 5° C./min, about 5° C./min to about 20° C./min, about 10° C./min to about 15° C./min, or about 20° C./min.

The practical cell voltage of the electrolyser system may be less than about 100 mV compared to the theoretical minimum voltage for water splitting at ambient temperature of 1230 mV. The catalyst composition micro-porous and/or nano-porous structure of the electrode may reduce the cell voltage to 0 mV for water splitting, i.e., the electrolyser system may become an autonomous electrolyser and operate without an applied voltage. By using doping agents, including, but not limited to B and N, the cathodic potential may be shifted toward more positive values and the anodic potential may be shifted toward more negative values. The hydrogen production reaction may become spontaneous without any external power requirement. The voltage of hydrogen reduction becomes far more positive than hydrazine or urea oxidation under low pH values for the cathodic side of an electrolysis cell and high pH values for the anodic side of an electrolysis cell. The low pH values may be at least about 0, about 0 to about 5.5, about 2.5 to about 5, about 2.5 to about 4.5, about 3 to about 4, or about 5.5. The high pH values may be at least about 8, about 8 to about 14, about 9 to about 13, about 10 to about 12, or about 14. Hydrogen production then becomes thermodynamically favorable and occurs spontaneously as long as the concentration of the salts in both sides are maintained. Therefore, a nitrogen-compound assisted hydrogen electrolyser may work autonomously to produce gaseous hydrogen and may also produce electricity. A high electrolysis cell current density of about 1 A·cm⁻² may result from the incorporation of metals or mixed metal-metal oxide nanoparticles into an electrode.

The electrolyser system may comprise an anode cell and/or a cathode cell. The overall potential of the anode cell may be less than about 250 mV, about 250 mV to about 0 mV, about 225 mV to about 10 mV, about 200 mV to about 50 mV, about 150 mV to about 100 mV, or about 250 mV at a current density of about 10 mA·cm⁻². The overall potential in the cathode cell may be less than about 100 mV, about 0 mV to about 100 mV, about 5 mV to about 99 mV, about 10 mV to about 97 mV, about 15 mV to about 95 mV, about 20 mV to about 90 mV, about 30 mV to about 80 mV, about 40 mV to about 70 mV, about 50 mV to about 60 mV, or about 100 mV at current density of 10 mA·cm⁻².

The cathode and anode may comprise the same material composition, i.e., function as bifunctional electrodes, or comprise different material compositions, e.g., function as separate electrodes. Bifunctional electrodes may have enhanced stability compared to separate electrodes because there is no difference in electrode composition, and the risk of galvanic cell coupling and subsequent corrosion and degradation of the electrodes is reduced or avoided. A Pt electrode with the cell volage of less than 100 mV may act as a performance benchmark for both anode and cathode.

The micro-structured and/or nano-structured foam may comprise a micro-structured and/or nano-structured catalyst comprising metal or mixed metal-metal oxide nanoparticles. A metal or mixed metal-metal oxide may be attached to a micro-structured and/or nano-structured foam using physical or chemical deposition methods including, but not limited to, magnetron sputtering, plasma coating, electrochemical coating, or a combination thereof. The metals may comprise, but are not limited to, Ti, V, Cr, Mn, Fe, Co, Ni, Cu, Zn, Zr, Nb, Mo, Ru, Pd, Ag, Cd, Hf, Ta, W, Re, Ir, Pt, Au, or a combination thereof. A metal oxide may be the oxide made from the above metals.

### INDUSTRIAL APPLICABILITY

The invention is further illustrated by the following non-limiting examples.

### EXAMPLE 1

Deposition of a compound material onto a substrate was performed by a sputtering method. After cleaning, the substrates were loaded into a sputtering chamber (various models such as DC, RF or magnetron were successfully tested) and a base pressure of ˜10⁻⁶ Torr (high vacuum) was reached. The main catalyst and the scarifying materials were co-deposited in an argon or an argon/oxygen/nitrogen atmosphere (for deposition of metal oxide or oxynitrides such as IrOₓ, NiN, NiOₓN) at a working pressure of between approximately 3 and 9 mTorr with a sputtering power ranging between 25 and 500 W and gas flow rate ranging from 1-100 standard cubic centimeters.

### EXAMPLE 2

Deposition of a compound material onto a substrate was performed by an electrochemical deposition. There were several different methods. In one aspect, the electrochemical method was done by using a pulsed electrodeposition method or by forming a core-shell structure (scarifying material as core and main catalyst as shell). Temperature of the bath used for the electrochemical method was maintained using a constant temperature thermostat. The solutions were freshly prepared using DI water and AnalaR grade chemicals. Table 1 and Table 2 give examples of solutions and salts used for electrochemical deposition.

TABLE 1
AEM Electrode Bath Composition.

| Technology | Electrode | Salts | Buffer | Surfactant | Complexing agent | Reaction initiator |
|---|---|---|---|---|---|---|
| AEM | Cathode | NiCl₂•6H₂O | Boric acid- | polyvinyl- | Trisodium citrate | chloroplatinic acid |
| | | FeCl₂•4H₂O | Sodium | pyrrolidone | dihydrate | hexahydrate |
| | | CoCl₂•6H₂O | Borate | (PVP) | (C6H5Na3O7•2H2O) | (H2PtCl6•6H2O) |
| | | (NH₄)₂MoO₄ | | | | |
| | Anode | NiCl₂•6H₂O | | | | |
| | | FeCl₂•4H₂O | | | | |
| | | ZnCl₂ | | | | |

TABLE 2
PEM Electrode Bath Composition.

| Technology | Electrode | Salts | Additives |
|---|---|---|---|
| PEM | Cathode | Ti/H₂PtCl₆ | HCl |
| | | CoCl₂•6H₂O | |
| | Anode | Ti/IrCl₄•H₂O | (COOH)₂•2H₂O + |
| | | ZnCl₂ | H₂O₂ + K₂CO₃ |

### EXAMPLE 3

Electrodeposition of materials was carried out using direct and pulse currents by potentiostat. The current value and time depended on the thickness and morphology of coating and the range of grain size targeted. Electroplating time was in the range of 15 minutes to 1 hour. The applied current ranged from 75 mA/cm² to 500 mA/cm². For pulse method, a square wave with tₒₙ=50 [symbol] S−5000 [symbol] S, and t_{off}=10 [symbol] S−1000 [symbol] S was used.

### EXAMPLE 4

Post-treatment of the deposited compound materials on the substrate was carried out through leaching and doping. By leaching of the scarifying materials from the compound materials, the microstructures of the catalyst materials were formed. This process was done by selective etching. In the selective etching, only specific materials were etched with a negligible effect on the other materials in the system.

### EXAMPLE 5

A nickel substrate was prepared. Nickel powders were milled in a ball mill with ethanol, two polyvinyl alcohol (“PVA”) polymers of low and high molecular weights, a surfactant e.g., sodium hexametaphosphate, was added and the slip was spray dried into a spherical granulated powder, sieved to a particle size of 20 μm-200 μm and uniaxially compacted using a punch and die to a pressure of 200 N/mm². The compacts were ejected from the die, placed on a sinter tray and sintered at 700° C. for 2 hours. A porous microstructure resulted with a density of 2.8 g/cm³ to 3.4 g/cm³. The catalyst material was blended into a thick but spreadable slurry and applied to the surface of the sintered substrate and sintered again to produce a multi-layered structure. The catalyst layer thickness ranged from 1 μm up to 150 μm and multiple layers were optionally applied.

### EXAMPLE 6

A metal substrate was prepared. Metal powders were milled with a suitable solvent, glycerol trioleate and various molecular weights of polyethylene glycol to create a slurry ranging from 1 Pa·s to 4 Pa·s at a shear rate of 100 s⁻¹. The slurries were cast over nickel foam using a doctor blade technique into films ranging from 1 μm to 2000 μm in thickness. The film was dried in situ and then removed and subject to a binder burnout step (de-waxing) followed by sintering between 500° C. and 1100° C. to produce a porous multi-layered structure.

### EXAMPLE 7

A nickel-titanium substrate was prepared. Nickel and titanium based powder mixtures were milled, with a commercial carrageenan added to them. A carrageenan is a large molecule polysaccharide that is used to form a gel network. The milled mixture was heated to 85° C.-95° C. when mixing the additives. Above 60° C., the slurry remained in a liquid state, but below this, the slurry set into a gel over time. The slurries were spread out over nickel foam (or similar porous structure) and allowed to cool and set. After drying under vacuum for several hours, the parts were sintered between 500° C. and 1100° C.

The preceding examples can be repeated with similar success by substituting the generically or specifically described components and/or operating conditions of embodiments of the present invention for those used in the preceding examples.

Note that in the specification and claims, “about” or “approximately” means within twenty percent (20%) of the amount or value given.

Embodiments of the present invention can include every combination of features that are disclosed herein independently from each other. Although the invention has been described in detail with particular reference to the disclosed embodiments, other embodiments can achieve the same results. Variations and modifications of the present invention will be obvious to those skilled in the art and it is intended to cover in the appended claims all such modifications and equivalents. The entire disclosures of all references, applications, patents, and publications cited above are hereby incorporated by reference.

Unless specifically stated as being “essential” above, none of the various components or the interrelationship thereof are essential to the operation of the invention. Rather, desirable results can be achieved by substituting various components and/or reconfiguring their relationships with one another.

What is claimed is:

1. A system for electrolyzing a solution comprising:
a first vessel in communication with at least one electrolyser stack comprising:
at least one bipolar electrode comprising:
a bipolar plate;
a porous transport layer; and
a catalyst comprising a binder;
said bipolar plate, said porous transport layer, and said catalyst fused together into a single component;
at least one separator; and
a second vessel in communication with said at least one electrolyser stack.

2. The system of claim 1 further comprising a substrate.

3. The system of claim 2 wherein said substrate supports said catalyst.

4. The system of claim 2 wherein said substrate comprises an alloying material.

5. The system of claim 1 wherein said binder comprises a primary element.

6. The system of claim 5 wherein said primary element comprises nickel.

7. The system of claim 1 wherein said binder comprises a secondary element.

8. The system of claim 7 wherein said secondary element comprises phosphorous.

9. The system of claim 1 wherein said binder is nickel-phosphorous.

10. A method for manufacturing a catalyst comprising a binder, the method comprising:
contacting a primary element with a secondary element to form a binder material;
contacting the binder material with a primary catalyst material to form a binder material and primary catalyst material mixture; and
sintering the binder material and primary catalyst material mixture.

11. The method of claim 10 wherein the primary element comprises nickel.

12. The method of claim 10 wherein the secondary element comprises phosphorous.

13. A composition comprising:
a primary catalyst; and
a binder.

14. The composition of claim 13 wherein said primary catalyst comprises a nickel alloy.

15. The composition of claim 13 wherein said primary catalyst comprises a cobalt alloy.

16. The composition of claim 13 wherein said primary catalyst comprises a transition metal.

17. The composition of claim 13 wherein said primary catalyst comprises a platinum group metal.

18. The composition of claim 13 wherein said binder comprises nickel.

19. The composition of claim 13 wherein said binder comprises phosphorous.

20. The composition of claim 13 wherein said composition is a sintered composition.
